(19) United States
(12) Patent Application Publication
(10) Pub. No.: US 2012/0267237 A1
(43) Pub. Date: Oct. 25, 2012

(54) Production of Nanoparticles

(75) Inventor: Alistair Kean, Oxfordshire (GB)

(73) Assignee: Mantis Deposition Limited, Oxfordshire (GB)

(21) Appl. No.: 13/497,176

(22) PCT Filed: Sep. 17, 2010
(86) PCT No.: PCT/GB10/01748

§ 371 Date: Jul. 13, 2012

(30) Foreign Application Priority Data
Sep. 21, 2009 (GB) 0916509.3

(51) Int. Cl. C23C 14/35

(52) U.S. Cl. 204/192.1; 204/298.08

(57) ABSTRACT

We have found that a pulsed DC supply is surprisingly beneficial in the use of sputter deposition for creating nanoparticles. The deposition rate is increased, and the particle size can be tuned so that it clusters around a specific value. A method of sputter deposition is therefore disclosed, comprising the steps of providing a magnetron, a sputter target, and an AC power supply or a pulsed DC power supply for the magnetron, sputtering particles from the sputter target into a chamber containing an inert gas, allowing the particles to coalesce into nanoparticles, and controlling the frequency of said AC power supply or said pulsed DC power supply to take one of a plurality of frequency values, each frequency value corresponding to a respective size distribution of said nanoparticles. The power supply frequency is preferably between 75 kHz and 150 kHz as this appears to yield optimal results. A corresponding apparatus for generating nanoparticles is also disclosed.

### FIELD OF THE INVENTION

The present invention relates to techniques and apparatus for use in producing nanoparticles.

### BACKGROUND ART

Sputter deposition is a well-known method for the vacuum deposition of materials. A DC magnetron is employed to create a plasma immediately above a “target” (i.e. a sample of the material to be deposited). Ions in the plasma strike the target surface repeatedly and force the evaporation of material from the target surface. This material then condenses locally, or is otherwise processed.

Some target materials are problematic in that they oxidise, for example Titanium. The insulating oxide layer inhibits the sputtering process, but this is overcome by employing an alternating (AC) electrical drive (or a pulsed DC electrical drive) to the magnetron instead of a DC drive. This drive is arranged to include brief positive excursions; thus whilst the drive is negative, the material is sputtered and whilst the drive is positive, the target surface is cleaned by the plasma.

### SUMMARY OP THE INVENTION

We have found that a pulsed supply is, surprisingly, beneficial in the deposition of other materials (such as non-oxidising materials) for the purpose of creating nanoparticles. The deposition rate is increased, and the particle size can be tuned so that it dusters around a specific value.

We therefore propose a method of generating nanoparticles, comprising the steps of providing a magnetron, a sputter target, and an AC power supply or a pulsed DC power supply for the magnetron, sputtering particles from the sputter target into a chamber containing an inert gas, allowing the particles to coalesce into nanoparticles, and controlling the frequency of said AC power supply or said pulsed DC power supply to take one of a plurality of frequency values, each frequency value corresponding to a respective size distribution of said nanoparticles.

The frequency of the pulsed or AC power supply is preferably between 75 kHz and 150 kHz, as this appears to yield optimal results.

The invention also envisages apparatus for generating nanoparticles, comprising a magnetron, a sputter target, and at least one of an AC power supply and a pulsed DC power supply for the magnetron, a chamber containing at least the sputter target and an inert gas surrounding the sputter target, thereby to allow particles from the putter target to coalesce into nanoparticles; and a power controller adapted to control the frequency of said AC power supply or said pulsed DC power supply to take one of a plurality of frequency values, each frequency value corresponding to a respective size distribution of said nanoparticles.

The invention also relates to the production of nanoparticles by the above routes, to nanoparticles so produced, and to articles bearing or containing such nanoparticles.

### BRIEF DESCRIPTION OF THE DRAWINGS

An embodiment of the present invention will now be described by way of example, with reference to the accompanying figures in which;

FIG. 1 shows (schematically) a typical sputter deposition arrangement;

FIG. 2 shows (schematically) the arrangement used to form nanoparticles;

FIG. 3 shows results obtained by varying the frequency of a pulsed DC power supply, in terms of multiple size/number spectra of the nanoparticles produced;

FIG. 4 shows, for the data in FIG. 3, the variation in peak nanoparticle size with power supply frequency; and

FIG. 5 shows, for the data in FIG. 3, the variation with power supply frequency of nanoparticle numbers over a threshold.

### DETAILED DESCRIPTION OF THE EMBODIMENTS

FIG. 1 shows (schematically) a sectional view of the arrangement of a sputter deposition apparatus. A target 2 is mounted over a magnetron 4 which is supplied by a power supply 6. The magnetron 4 creates a plasma 8 over the target 2; a common arrangement for this is in a “racetrack” pattern, i.e. an oval when viewed from above. Particles within the plasma impact the surface of the target 2 and cause the forced evaporation of atoms from the target, gradually consuming the target 2 in the vicinity of the plasma B and causing a flow 9 of evaporated material away from the apparatus.

The above-described sputter deposition apparatus can be used for the production of nanoparticles through a process of ‘gas condensation’, as described in our earlier application GB2430202A. An atomic vapour is generated (through a one of a variety of means) in a (relatively) high pressure environment, which causes the atoms to lose energy through collisions with the background gas (usually an inert or noble gas such as argon or helium) and subsequently combine with other atoms to form nanoparticles.

By providing a controlled drift between the point of vapour generation and the exit of the high-pressure condensation region, the combined gas; nanoparticle stream can be made to exit the condensation zone, at which point the nanoparticle growth generally terminates. The effect of this is to subject each nanoparticle to a strict vapour density and pressure path, and thereby ensures that the size of the nanoparticles on reaching the exit of the condensation zone are broadly similar leading to a narrow size distribution.

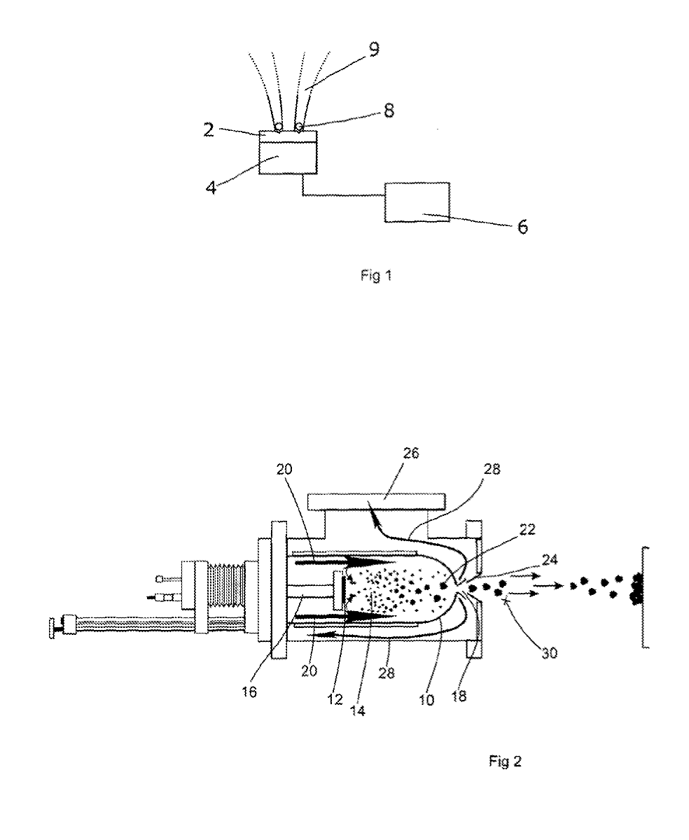

FIG. 2 shows the apparatus and method in schematic form. A chamber 10 contains a magnetron sputtering source 12 to generate the vapour 14, mounted on a linearly translatable substrate 16. The interior of the chamber 10 contains an inert gas at a relatively high pressure of a hundred millitorr or more, say up to 5 torr.

The inert gas is fed into the chamber 10 from a point behind the magnetron 12 and extracted from an exit aperture 18 directly ahead of the magnetron 12. This creates a gas flow through the chamber as indicated by arrows 20 and establishes a drift of the vapour 14. During its transit to the exit aperture 18, the vapour condenses to form a nanoparticle cloud 22.

Alternatively, any method capable of creating an atomic vapour can be used, such as evaporative techniques (e.g. thermal evaporation, MBE) or chemical techniques (e.g. CVD),

On exiting the condensation zone defined by the chamber 10, the beam is subject to a large pressure differential and undergoes supersonic expansion, This expanded beam then impinges upon a second aperture 24, which allows the central portion of the beam to pass through, while the background gas and smaller nanoparticles do not pass through. The background gas is then collected by a pumping port 26 for re-circulation or disposal, as indicated by arrows 28. This provides a further refinement of the beam as the smaller particles are ‘filtered’ out.

By using magnetron sputtering, a high fraction of the nanoparticles produced are negatively charged. This allows the particles to be accelerated electrostatically across a vacuum 30 to a substrate or object, and thus gain kinetic energy. This can be achieved by raising the substrate or object to a suitably high potential. Non-conductive substrates can be placed behind a conductive mask having an appropriately shaped aperture in the line of sight of the particle beam.

The kinetic energy acquired in flight is lost on impact by way of deformation of the particles. The degree of deformation naturally depends on the energy imparted to the particles in flight. At very high energies, the nanoparticle structure may be lost and the resultant film will be essentially bulk material, At very low energies, the process will be akin to condensation and the film may be insufficiently adherent. Between these extremes, there is scope for deformation of the particles that is mild enough for the surface of the film to retain nanoparticulate properties but for the interface with the substrate to be adherent.

Where the particles are generated by methods other than sputtering, they can be ionised via any suitable method and then accelerated in like fashion.

In one exempt mixture of Helium and Argon gas are introduced into a condensation cavity to generate a pressure between 0.01 and 0.5 torr, depending on the coating conditions. A negative voltage, typically between 200V and 1000V is introduced to a silver target, held in the magnetron sputtering device contained within the condensation cavity. This voltage induces a discharge which acts to sputter silver atoms from the surface of the target. The high pressure gaseous environment causes the silver atoms to lose energy through collisions and eventually to combine with other silver atoms to form particles. Negatively and positively charged particles are formed in the discharge around the magnetron, but only the negatively charged particles can escape the electric field generated by the negative voltage on the target. These negatively charged particles grow as they drift towards the exit of the condensation zone in a controlled manner.

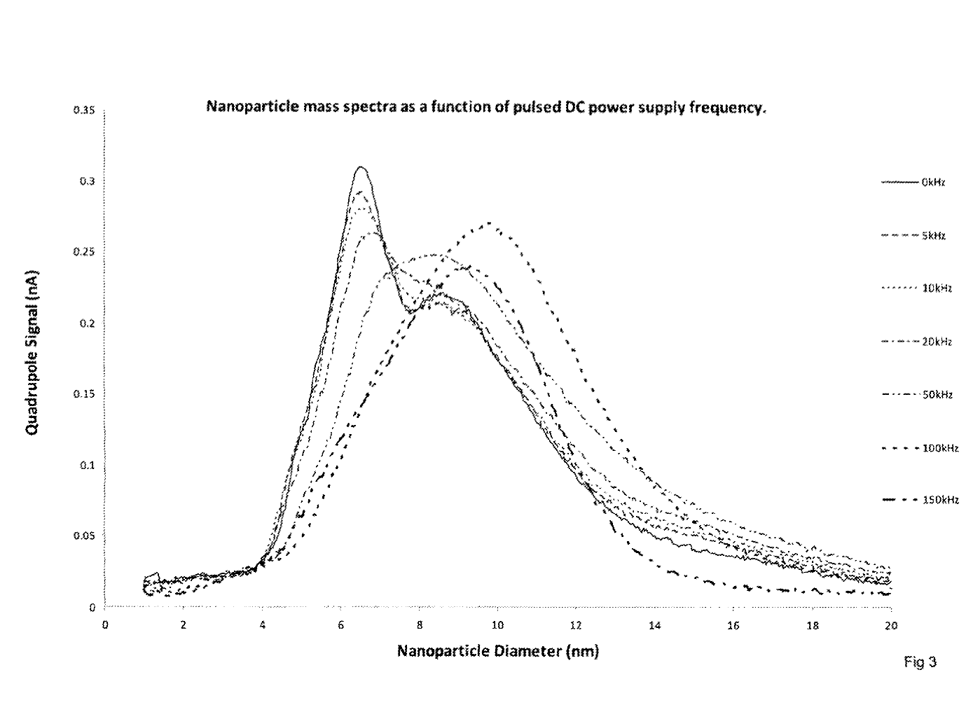

FIG. 3 is a graph showing the variation of nanoparticle diameter (and therefore mass being deposited) by increasing the frequency of a pulsed DC supply voltage to a copper target. The graph shows a measure of the number of nanaparticles of a specific diameter, with different lines for different frequencies between 0 kHz (i.e. a simple unpulsed DC supply) and 150 kHz. The optimum frequency in this case was about 100-150 kHz, at which point the size distribution was qualitatively different to that at 0 kHz. In this case the deposition rate was enhanced by about a factor of 5.

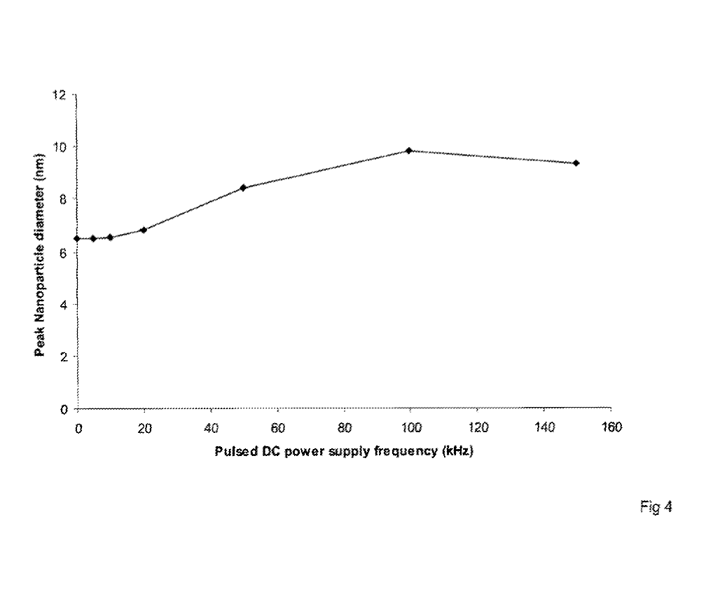

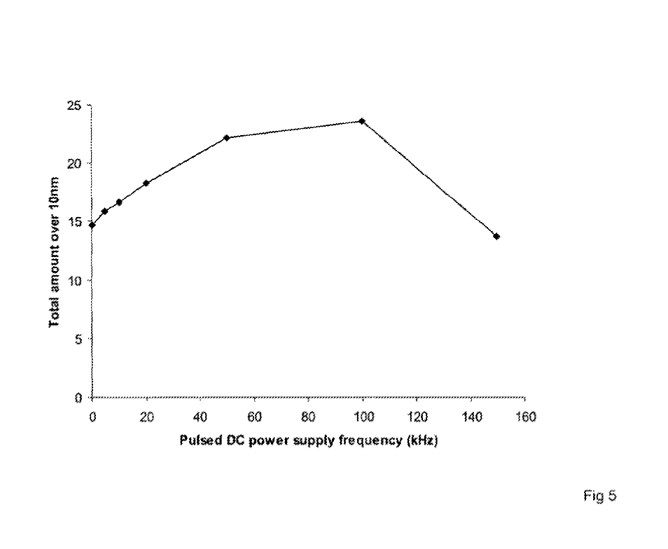

FIG. 4 shows the variation in the peak nanoparticle diameter with the frequency of the pulsed DC source, based on the same data as FIG. 3. It can be seen that the nanoparticle diameter increases with a frequency as low as 20 kHz, with a distinct maximum by 50 kHz before plateauing at approximately 100 kHz.

FIG. 5 presents a slightly different view (again) of the same data, plotting the total number of nanoparticles (on an arbitrary scale) over a threshold of 10 nm against the power supply frequency. Again, a clear difference can be seen as the supply frequency varies, with a distinct increase in the nanoparticle size as soon as the supply becomes pulsed, rising steadily to 100 kHz. Such behaviour is not to be expected using a non-oxidising target such as copper.

Similar results were obtained using the pulsed dc supply with tantalum and titanium, with the deposition rate being enhanced in both cases. By way of example, a titanium target typically achieved a deposition rate of ˜1.5 Å/s using straight DC voltage, but with a pulsed DC supply a rate of ˜6.0 Å/s could be achieved. The experimental conditions for this were 40 sccm (standard cubic centimetres per minute) of argon, 94 W sputter power, and a 70 kHz pulse frequency.

Similar results can be expected with all metal targets. For classical sputtering an alternating supply is used for ‘trickier’ targets such as indium tin oxide and zinc oxide, which are conductive but can suffer from oxide contamination. The alternating supply helps to keep the target clean. This may be a very good technique for the production of these materials as nanoparticles, as the deposition of these materials is challenging, and could be achieved efficiently using the above pulsed DC supply.

It will of course be understood that many variations may be made to the above-described embodiment without departing from the scope of the present invention.

1. A method of generating nanoparticles, comprising the steps of:
providing a magnetron, a sputter target, and an AC power supply or a pulsed DC power supply for the magnetron;
sputtering particles from the sputter target into a chamber containing an inert gas, allowing the particles to coalesce into nanoparticles; and
controlling the frequency of said AC power supply or said pulsed DC power supply to take one of a plurality of frequency values, each frequency value corresponding to a respective size distribution of said nanoparticles.

2. A method according to claim 1 in which the sputter target is a non-oxidising metallic material.

3. A method according to claim 2 in which the sputter target is copper.

4. A method according to claim 1 in which the sputter target is one of indium tin oxide, zinc oxide, tantalum and titanium.

5. A method according to claims 1 in which the power supply is at a frequency between 75 kHz and 150 kHz.

6. Apparatus for generating nanoparticles, comprising:
a magnetron, a sputter target, and at least one of an AC power supply and a pulsed DC power supply for the magnetron;
a chamber containing at least the sputter target and an inert gas surrounding the sputter target, thereby to allow particles from the putter target to coalesce into nanoparticles; and
a power controller adapted to control the frequency of said AC power supply or said pulsed DC power supply to take one of a plurality of frequency values, each frequency value corresponding to a respective size distribution of said nanoparticles.

7. Apparatus for generating nanoparticles according to claim 6 in which the sputter target is one of indium tin oxide, zinc oxide, tantalum and titanium.

8. Apparatus for generating nanoparticles according to claim 6 in which the sputter target is copper.

9. Apparatus for generating nanoparticles according to claim 8 in which the power supply is at a frequency between 75 kHz and 150 kHz.

10. A method of generating nanoparticles substantially as herein disclosed with reference to and/or as illustrated in the accompanying figures.

11. Apparatus for generating nanoparticles substantially as herein disclosed with reference to and/or as illustrated in the accompanying figures.
